(19) United States
(12) Patent Application Publication
(10) Pub. No.: US 2024/0084172 A1
(43) Pub. Date: Mar. 14, 2024

(54) ADHESIVE COMPOSITION, FILM ADHESIVE, AND SEMICONDUCTOR PACKAGE USING FILM ADHESIVE AND PRODUCING METHOD THEREOF

(71) Applicant: FURUKAWA ELECTRIC CO., LTD., Tokyo (JP)

(72) Inventors: Minoru MORITA, Tokyo (JP); Tomohito KAJIHARA, Tokyo (JP); Yota OTANI, Tokyo (JP); Hiromitsu MARUYAMA, Tokyo (JP)

(73) Assignee: FURUKAWA ELECTRIC CO., LTD., Tokyo (JP)

(21) Appl. No.: 18/388,278

(22) Filed: Nov. 9, 2023

Related U.S. Application Data
(63) Continuation of application No. PCT/JP2022/044032, filed on Nov. 29, 2022.

(30) Foreign Application Priority Data
Dec. 27, 2021 (JP) 2021-213386

(51) Int. Cl. C09J 7/10; C09J 7/35; C09J 7/40; H01L 21/78; H01L 23/00; H01L 25/065

(52) U.S. Cl. CPC C09J 7/10; C09J 7/35; C09J 7/405; H01L 21/78; H01L 24/27; H01L 24/29; H01L 24/32; H01L 24/83; H01L 25/0657; C08K 3/36; C09J 2400/16; C09J 2463/00; C09J 2475/00

(57) ABSTRACT

Disclosed are: an adhesive composition including an epoxy resin (A), an epoxy resin curing agent (B), a polyurethane resin (C), and an inorganic filler (D), in which the polyurethane resin (C) has a storage elastic modulus at 25° C., in a dynamic viscoelastic analysis, of 8.0 MPa or higher, a proportion of the polyurethane resin (C) based on a total content of the epoxy resin (A) and the polyurethane resin (C) is from 2.0 to 50.0 mass %, and a maximum tensile stress in a stress-strain curve when a tensile strength is applied to a film adhesive formed using the adhesive composition is 7.0 MPa or higher; a film adhesive using the adhesive composition; a semiconductor package; and a producing method thereof.

### CROSS-REFERENCE TO RELATED APPLICATIONS

This application is a Continuation of PCT International Application No. PCT/JP2022/044032 filed on Nov. 29, 2022, which claims priority under 35 U.S.C. § 119 (a) to Japanese Patent Application No. 2021-213386 filed in Japan on Dec. 27, 2021. Each of the above applications is hereby expressly incorporated by reference, in its entirety, into the present application.

### FIELD OF THE INVENTION

The present invention relates to an adhesive composition, a film adhesive, and a semiconductor package using the film adhesive and a producing method thereof.

### BACKGROUND OF THE INVENTION

Stacked MCPs (Multi Chip Package) in which semiconductor chips are multistacked have recently been widely spread. Such stacked MCPs are mounted as memory packages for mobile phones or portable audio devices. Further, along with development in the multi-functionality in mobile phones and the like, high densification and high integration of the package have also been advanced. Along with these advances, multistacking of the semiconductor chips has been advanced.

For bonding a circuit board and a semiconductor chip or bonding semiconductor chips in the production process of such a memory package, thermosetting film adhesives (die attach films, die bond films) have been used. Along with the trend toward multistacking of the chips, the die attach film has also become increasingly thinner. Also, as miniaturization in the wiring rule of the wafer has been advanced, heat is more likely to be generated on the surface of the semiconductor element. Therefore, in order to dissipate heat to the outside of the package, a thermally conductive filler is blended in the die attach film to realize high thermal conductivity.

As a material of a thermosetting film adhesive intended for so-called die attach film applications, for example, a composition obtained by combining an epoxy resin, a curing agent for the epoxy resin, a polymer compound, and an inorganic filler is known. As the polymer compound, it has been proposed to use a polyurethane resin or a phenoxy resin (e.g., Patent Literatures 1 and 2).

### CITATION LIST

### Patent Literature

Patent Literature 1: WO 2012/160916
Patent Literature 2: WO 20211033368

### SUMMARY OF INVENTION

### Technical Problem

A dicing die attach film has been known as an application of a die attach film. This dicing die attach film has a structure in which a dicing film and a die attach film are laminated, and the laminated structure as a whole functions as a dicing tape for fixing a semiconductor wafer when cutting and separating (dicing) the semiconductor wafer into individual chips. Next, the die attach film, cut and diced together with the semiconductor wafer by dicing, is separated from the dicing film together with the semiconductor chip when picking up the cut semiconductor chip. During the mounting after the pickup, the semiconductor chip is bonded to a lead frame, a circuit board, a semiconductor chip, and the like via an adhesive layer derived from the die attach film.

This dicing die attach film is generally provided in a form in which pre-cut processing is performed into a desired shape, in consideration of workability such as attachment to a semiconductor wafer or fixing to a ring frame at the time of dicing. As an example of the form of the dicing die attach film subjected to the pre-cut processing, for example, there is a form in which a die attach film (film adhesive) having a circular shape corresponding to a semiconductor wafer is repeatedly formed on a long base material (release film) at regular intervals in the length direction, and a dicing film having a diameter slightly larger than that of the die attach film is concentrically laminated thereon.

In the production of a dicing die attach film subjected to pre-cut processing,
1) an adhesive composition is applied to the entire surface of a long base material and dried, a cut is made in the obtained die attach film with a blade having a shape corresponding to a semiconductor wafer (circular shape), and the die attach film on the outer side of the circular portion (unnecessary portion) is wound and peeled off from the base material while leaving the circular portion on the base material (this operation is referred to as “winding of unnecessary portion”) to form a circular die attach film, and
2) a dicing tape is laminated on the entire surface of the base material from above the circular die attach film, a cut is made in the dicing tape with a blade having a shape corresponding to the ring frame (circular shape), and the dicing tape on the outer side of the circular portion is wound and peeled off from the base material while leaving the circular portion.

In the winding of the unnecessary portion of the circular portion, the unnecessary portion may cause breakage during winding. When such breakage occurs, it is necessary to temporarily stop the operation of winding the unnecessary portion, make it ready for winding, and then restart the operation. Thus, continuous winding cannot be performed, which causes a decrease in productivity (pre-cut processability). This defect in pre-cut processability becomes more apparent as the amount of the inorganic filler filled into the die attach film increases and the die attach film becomes thinner.

In addition, as the die attach film becomes thinner, the following two problems tend to become apparent in the semiconductor assembly process.

The first problem is a problem of lamination performance where air (voids) is easily entrapped between an adherend and a die attach film in a step of laminating the die attach film on a back surface of the adherend such as a semiconductor wafer. The entrapped air reduces the adhesive strength after thermal curing.

The second problem is a problem of cutting performance where cutting debris generated when the adherend and the die attach film are integrally diced adhere to the surface of the adherend, and contamination residues are easily occurred. This problem of cutting performance is caused due to powdery debris formed by cutting the die attach film while using the dicing blade when the die attach film is cut, which debris are further melted by heat generated by the rotation of the dicing blade and become thread-like.

The present invention provides a film adhesive excellent in all of pre-cut processability, lamination performance, and cutting performance during a dicing step, and an adhesive composition suitable for obtaining the same. Further, the present invention provides a semiconductor package using the film adhesive and a producing method thereof.

### Solution to Problem

As a result of intensive studies in view of the above problems, the present inventors have found that the above problems can be solved by controlling the maximum tensile stress of a film adhesive when the film adhesive is formed (when a solvent is removed from an adhesive composition to form a B-stage state (state before curing)) to a specific value or higher by using a given amount of a polyurethane resin having a predetermined storage elastic modulus in an adhesive composition having a composition containing, in combination, an epoxy resin, an epoxy resin curing agent, the polyurethane resin, and an inorganic filler.

The present invention is based on the above findings, and after further investigation, has been completed.

The above problems of the present invention have been solved by the following means.

[1]

An adhesive composition including:
an epoxy resin (A);
an epoxy resin curing agent (B);
a polyurethane resin (C); and
an inorganic filler (D),
wherein the polyurethane resin (C) has a storage elastic modulus at 25° C., in a dynamic viscoelastic analysis, of 8.0 MPa or higher,
wherein a proportion of the polyurethane resin (C) based on a total content of the epoxy resin (A) and the polyurethane resin (C) is from 2.0 to 50.0 mass %, and
wherein a maximum tensile stress in a stress-strain curve when a tensile strength is applied to a film adhesive formed using the adhesive composition is 7.0 MPa or higher.
   [2]

The adhesive composition described in [1], wherein when the film adhesive formed using the adhesive composition is heated at a temperature elevation rate of 5° C./min from 25° C., a melt viscosity at 70° C. is 50000 Pa-s or less.

A film adhesive obtained from the adhesive composition described in [1] or [2].

[4]

The film adhesive described in [3], which has a thickness of 1 to 20 μm.

[5]

A method of producing a semiconductor package, including:
a first step of providing an adhesive layer by thermocompression bonding the film adhesive described in [3] or [4] to a back surface of a semiconductor wafer in which at least one semiconductor circuit is formed on a surface, and providing a dicing film via the adhesive layer;
a second step of dicing the semiconductor wafer and the adhesive layer simultaneously to obtain a semiconductor chip with an adhesive layer, which includes the semiconductor chip and a piece of the film adhesive, on the dicing film;
a third step of peeling the semiconductor chip with an adhesive layer off from the dicing film, and thermocompression bonding the semiconductor chip with an adhesive layer and a circuit board via the adhesive layer; and
a fourth step of thermally curing the adhesive layer.
   [6]

A semiconductor package wherein a semiconductor chip and a circuit board, or semiconductor chips are bonded via a thermally cured body of the film adhesive described in [3] or [4],
In the present invention, the numerical ranges expressed with the term “to” refer to ranges including, as the lower limit and the upper limit, the numerical values before and after the term “to”.

### Advantageous Effects of Invention

In the film adhesive of the present invention, an unnecessary portion is less likely to be broken at the time of winding the unnecessary portion in pre-cut processing, formation of voids can be suppressed at the time of bonding (laminating) the film adhesive to an adherend, and occurrence of cutting debris during dicing can be suppressed.

The adhesive composition of the present invention is suitable for obtaining the film adhesive.

According to the producing method of the present invention, a semiconductor package can be produced using the film adhesive.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of a method of producing a semiconductor package of the present invention.

FIG. 3 is a schematic longitudinal cross-sectional view illustrating a preferred embodiment of a third step of a method of producing a semiconductor package of the present invention.

FIG. 4 is a schematic longitudinal cross-sectional view illustrating a preferred embodiment of a step of connecting a bonding wire of a method of producing a semiconductor package of the present invention.

FIG. 5 is a schematic longitudinal cross-sectional view illustrating an example of an embodiment of multistacking of a method of producing a semiconductor package of the present invention.

FIG. 6 is a schematic longitudinal cross-sectional view illustrating an example of an embodiment of another multistacking of a method of producing a semiconductor package of the present invention.

FIG. 7 is a schematic longitudinal cross-sectional view illustrating a preferred embodiment of a semiconductor package produced by a method of producing a semiconductor package of the present invention.

### DESCRIPTION OF EMBODIMENTS

### <<Adhesive Composition>>

The adhesive composition of the present invention is a composition suitable for forming a film adhesive of the present invention.

The adhesive composition of the present invention contains an epoxy resin (A), an epoxy resin curing agent (B), a polyurethane resin (C), and an inorganic filler (D). The polyurethane resin (C) has a storage elastic modulus at 25° C., in a dynamic viscoelastic analysis, of 8.0 MPa or higher. The proportion of the polyurethane resin (C) based on the total content of the epoxy resin (A) and the polyurethane resin (C) is controlled to 2 to 50 mass %.

The maximum tensile stress in the stress-strain curve when a tensile strength is applied to a film adhesive formed using this adhesive composition is 7.0 MPa or higher. Details of the maximum tensile stress will be described in the section [Film adhesive] described later. Further, it is preferable that the film adhesive formed using the adhesive composition exhibits characteristics (e.g., melt viscosity at 70° C. and tensile elastic modulus) described in the section [Film adhesive] below.

Hereinafter, each component contained in the adhesive composition will be described.

### <Epoxy Resin (A)>

The epoxy resin (A) is a thermosetting resin having an epoxy group, and preferably has an epoxy equivalent of 500 g/eq or less. The epoxy resin (A) may be liquid, solid, or semi-solid. The liquid in the present invention means that the softening point is less than 25° C. The solid means that the softening point is 60° C. or more. The semi-solid means that the softening point is between the softening point of the liquid and the softening point of the solid (25° C. or more and less than 60° C.). As the epoxy resin (A) used in the present invention, the softening point is preferably 100° C. or less from the viewpoint of obtaining a film adhesive that can reach low melt viscosity in a preferable temperature range (for example, 60 to 120° C.). Incidentally, in the present invention, the softening point is a value measured by the softening point test (ring and ball) method (measurement condition: in accordance with JIS-K7234:1986).

In the epoxy resin (A) used in the present invention, the epoxy equivalent is preferably from 150 to 450 g/eq from the viewpoint of increasing the crosslinking density of a thermally cured body. Note that, in the present invention, the epoxy equivalent refers to the number of grams of a resin containing 1 gram equivalent of epoxy group (g/eq).

The weight average molecular weight of the epoxy resin (A) is usually preferably less than 10000 and more preferably 5000 or less. The lower limit is not particularly limited, but is practically 300 or more.

The weight average molecular weight is a value obtained by GPC (Gel Permeation Chromatography) analysis (hereinafter, the same applies to other resins unless otherwise specified).

Examples of the skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among these skeletons, a triphenylmethane type, a bisphenol A type, a cresol novolac type, and an orthocresol novolac type are preferable from the viewpoint of being capable of obtaining a film adhesive having low resin crystallinity and good appearance.

The content of the epoxy resin (A) is preferably 3 to 70 parts by mass, preferably 10 to 60 parts by mass, and more preferably 15 to 50 parts by mass as well as preferably 20 to 40 parts by mass, preferably 20 to 30 parts by mass, or preferably 20 to 26 parts by mass based on 100 parts by mass of the total content of components constituting the film adhesive (specifically, components other than a solvent, i.e., a solid content) in the adhesive composition of the present invention. By adjusting the content to the preferable upper limit or less, the state of the film (e.g., film tack property) is unlikely to be changed in the case of a small change in temperature, and at a temperature equal to or higher than the semiconductor assembly process temperature (e.g., 70° C. or higher for bonding to a wafer), melting can be performed.

### <Epoxy Resin Curing Agent (B)>

As the epoxy resin curing agent (B), any curing agents such as amines, acid anhydrides, and polyhydric phenols can be used. In the present invention, a latent curing agent is preferably used from the viewpoint of having a low melt viscosity, and being capable of providing a film adhesive that exhibits curability at a high temperature exceeding a certain temperature, has rapid curability, and further has high storage stability that enables long-term storage at room temperature.

Examples of the latent curing agent include a dicyandiamide compound, an imidazole compound, a curing catalyst composite-based polyhydric phenol compound, a hydrazide compound, a boron trifluoride-amine complex, an amine imide compound, a polyamine salt, a modified product thereof, or those of a microcapsule type. These may be used singly, or in combination of two or more types thereof. Use of an imidazole compound is more preferable from the viewpoint of providing even better latency (properties of excellent stability at room temperature and exhibiting curability by heating) and providing a more rapid curing rate.

The content of the epoxy resin curing agent (B) in the adhesive composition may be set appropriately, according to the type and reaction form of the curing agent. For example, the content can be 0.5 to 100 parts by mass, may be 1 to 80 parts by mass or 2 to 50 parts by mass, and is also preferably 4 to 20 parts by mass based on 100 parts by mass of the epoxy resin (A). In addition, when an imidazole compound is used as the epoxy resin curing agent (B), the content of the imidazole compound is preferably from 0.5 to 10 parts by mass or preferably from 1 to 5 parts by mass based on 100 parts by mass of the epoxy resin (A). Setting the content of the epoxy resin curing agent (B) to the preferable lower limit or more can further reduce the curing time. On the other hand, setting the content to the preferable upper limit or less can suppress excessive remaining of the curing agent in the film adhesive. As a result, moisture absorption by the remaining curing agent can be suppressed, and thus the reliability of the semiconductor device can be improved.

### <Polyurethane Resin (C)>

The polyurethane resin (C) is a polymer having a urethane (carbamic acid ester) bond in the main chain. The polyurethane resin (C) has a constituent unit derived from a polyol and a constituent unit derived from a polyisocyanate, and may further have a constituent unit derived from a polycarboxylic acid. One kind of the polyurethane resin may be used singly, or two or more kinds thereof may be used in combination.

The polyurethane resin (C) has a storage elastic modulus at 25° C., in a dynamic viscoelastic analysis, of 8.0 MPa or higher. The polyurethane resin (C) has a storage elastic modulus at 25° C. of preferably 50.0 MPa or higher, more preferably 70.0 MPa or higher, and still more preferably 90.0 MPa or higher. In addition, the polyurethane resin (C) has a storage elastic modulus at 25° C. of usually 1000.0 MPa or less, more preferably 800.0 MPa or less, still more preferably 700.0 MPa or less, and still more preferably 650.0 MPa or less. Thus, the storage elastic modulus is preferably from 8.0 to 1000.0 MPa, more preferably from 50.0 to 800.0 MPa or less, and still more preferably from 90.0 to 700.0 MPa.

The polyurethane resin (C) has a tan δ peak top temperature (same as a glass transition temperature, also referred to as Tg), in a dynamic viscoelastic analysis, of preferably −10° C. or higher, more preferably −5° C. or higher, still more preferably 0° C. or higher, still more preferably 2° C. or higher, and still more preferably 3° C. or higher. The Tg of the polyurethane resin (C) is usually 100° C. or lower, preferably 60° C. or lower, more preferably 50° C. or lower, and also preferably 45° C. or lower. When the Tg is within the above range, the pre-cut processability and the cutting performance during the dicing step can be further enhanced in the film adhesive.

The storage elastic modulus and Tg are determined by methods described in Examples described later. Specifically, a coating film is formed using a varnish obtained by dissolving a polyurethane resin in an organic solvent, and then dried to obtain a film made of the polyurethane resin. This film is measured by using a dynamic viscoelastic analyzer (trade name: Rheogel-E4000F, manufactured by UBM) under conditions: a measurement temperature range of 20 to 300° C., a temperature elevation rate of 5° C./min, and a frequency of 1 Hz. The storage elastic modulus at 25° C. is read from the measured value and taken as the storage elastic modulus, and the tan δ peak top temperature (temperature at which tan δ exhibits the maximum) is taken as the glass transition temperature (Tg).

The weight average molecular weight of the polyurethane resin (C) is not particularly limited, and a polyurethane resin having a weight average molecular weight within a range of 5000 to 500000 is usually used.

The content of the polyurethane resin (C) is from 2.0 to 50.0 mass % as a proportion of the polyurethane resin (C) based on the total content of the epoxy resin (A) and the polyurethane resin (C), and is preferably from 4.0 to 40.0 mass %, more preferably from 6.0 to 40.0 mass %, still more preferably from 7.0 to 40.0 mass %, still more preferably from 8.0 to 38.0 mass %, still more preferably from 10.0 to 35.0 mass %, and still more preferably from 10.0 to 30.0 mass %.

The polyurethane resin (C) can be synthesized by a conventional procedure, and can also be obtained from the market. Examples of a commercially available product that can be applied as the polyurethane resin (C) include Dynaleo VA-9320M, Dynaleo VA-9310MF, or Dynaleo VA-9303MF (all manufactured by TOYOCHEM CO., LTD.).

### <Inorganic Filler (D)>

As the inorganic filler (D), an inorganic filler usually used in the adhesive composition can be used without particular limitation.

Examples of the inorganic filler (D) include each inorganic powder made of ceramics, such as silica, clay, gypsum, calcium carbonate, barium sulfate, alumina (aluminum oxide), beryllium oxide, magnesium oxide, silicon carbide, silicon nitride, aluminum nitride, boron nitride; metal or alloys, such as aluminum, copper, silver, gold, nickel, chromium, lead, tin, zinc, palladium, solder; and carbons, such as carbon nanotube, carbon nanofiber, or graphene.

The average particle diameter (d50) of the inorganic filler (D) is not particularly limited, but is preferably 0.01 to 6.0 μm, preferably 0.01 to 5.0 μm, more preferably 0.1 to 3.5 μm, and still more preferably 0.3 to 3.0 μm from the viewpoint of making the film adhesive thinner. The average particle diameter (d50) is a so-called median diameter, and refers to a particle diameter at which the cumulative volume is 50% when the particle size distribution is measured by the laser diffraction scattering method and the total volume of the particles is defined as 100% in the cumulative distribution.

The Mohs hardness of the inorganic filler is not particularly limited, and is preferably 2 or more and more preferably from 2 to 9. The Mohs hardness can be measured with a Mohs hardness meter.

The inorganic filler (D) may contain a thermally conductive inorganic filler (inorganic filler having a thermal conductivity of 12 W/m·K or more) in an embodiment, or may contain a thermally non-conductive inorganic filler (inorganic filler having a thermal conductivity of less than 12 W/m·K) in an embodiment.

The inorganic filler (D) having thermal conductivity is a particle made of a thermally conductive material or a particle whose surface is coated with the thermally conductive material. The thermal conductivity of the thermally conductive material is preferably 12 W/m·K or more, and more preferably 30 W/m·K or more.

When the thermal conductivity of the thermally conductive material is the preferable lower limit or more, the amount of the inorganic filler (D) to be blended in order to obtain a desired thermal conductivity can be reduced. This suppresses increase in the melt viscosity of the die attach film, and enables to further improve the filling property of the film into the unevenness of the substrate at the time of compression bonding to the substrate. As a result, generation of voids can be more reliably suppressed.

In the present invention, the thermal conductivity of the thermally conductive material means the thermal conductivity at 25° C., and the literature value for each material can be used. In a case where there is no description in the literatures, for example, the value measured in accordance with JIS R 1611:2010 can be used in the case of ceramics, or the value measured in accordance with JIS H 7801:2005 can be used in the case of metals in substitution for the literature value.

Examples of the inorganic filler (D) having thermal conductivity include thermally conductive ceramics, and preferred examples thereof include alumina particles (thermal conductivity: 36 W/m·K), aluminum nitride particles (thermal conductivity: 150 to 290 W/m·K), boron nitride particles (thermal conductivity: 60 W/m·K), zinc oxide particles (thermal conductivity: 54 W/m·K), silicon nitride particles (thermal conductivity: 27 W/m·K), silicon carbide particles (thermal conductivity: 200 W/m·K), and magnesium oxide particles (thermal conductivity: 59 W/m·K).

In particular, alumina particles are preferable because of their high thermal conductivity, dispersibility and availability. Further, aluminum nitride particles and boron nitride particles are preferable from the viewpoint of having even higher thermal conductivity than that of alumina particles. In the present invention, alumina particles and aluminum nitride particles are preferable among these particles.

Additional examples include metal particles having higher thermal conductivity than ceramic, or particles surface-coated with a metal. Preferred examples include a single metal filler such as silver (thermal conductivity: 429 W/m·K), nickel (thermal conductivity: 91 W/m·K), and gold (thermal conductivity: 329 W/m·K); and polymer particles such as silicone resin particles or acrylic resin particles whose surfaces are coated by these metals.

In the present invention, gold or silver particles are more preferable from the viewpoint of, in particular, high thermal conductivity and resistance to oxidative deterioration.

In the present invention, it is also preferable to use alumina, silver, or silica as the inorganic filler (D).

The inorganic filler (D) may be subjected to surface treatment or surface modification. Examples of the surface treatment agent used for such surface treatment or surface modification include a silane coupling agent, phosphoric acid or a phosphoric acid compound, or a surfactant. Besides the items described in the present specification, the descriptions of a silane coupling agent, or phosphoric acid or a phosphoric acid compound, and a surfactant in the section of a thermally conductive filler in WO 2018/203527 or the section of an aluminum nitride filler in WO 2017/158994 can be applied, for example.

A method of blending the inorganic filler (D) to resin components such as the epoxy resin (A), the epoxy resin curing agent (B), and the polyurethane resin (C) includes a method in which a powder inorganic filler and, if necessary, a silane coupling agent, phosphoric acid or a phosphoric acid compound, and a surfactant are directly blended (integral blending method), and a method in which a slurry inorganic filler obtained by dispersing an inorganic filler treated with a surface treatment agent such as a silane coupling agent, phosphoric acid or a phosphoric acid compound, and a surfactant in an organic solvent is blended.

A method of treating the inorganic filler (D) with a silane coupling agent is not particularly limited. Examples thereof include a wet method of mixing the inorganic filler (D) and a silane coupling agent in a solvent, a dry method of mixing the inorganic filler (D) and a silane coupling agent in a gas phase, and the above integral blending method.

In particular, the aluminum nitride particles contribute to high thermal conductivity, but tend to generate ammonium ions due to hydrolysis. It is therefore preferable that the aluminum nitride particles are used in combination with a phenol resin having a low moisture absorption rate, and/or hydrolysis is suppressed by surface modification. As a surface modification method of the aluminum nitride, a method of providing a surface layer with an oxide layer of aluminum oxide to improve water proofness and then performing surface treatment with phosphoric acid or a phosphoric acid compound to improve affinity with the resin is particularly preferable.

The silane coupling agent is a compound in which at least one hydrolyzable group such as an alkoxy group or an aryloxy group is bonded to a silicon atom. In addition to these groups, an alkyl group, an alkenyl group, or an aryl group may be bonded to the silicon atom. The alkyl group is preferably an alkyl group substituted with an amino group, an alkoxy group, an epoxy group, or a (meth)acryloyloxy group, and more preferably an alkyl group substituted with an amino group (preferably, a phenylamino group), an alkoxy group (preferably, a glycidyloxy group), or a (meth)acryloyloxy group.

Examples of the silane coupling agent include 2-(3,4-epoxycyclohexyl) ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, and 3-methacryloyloxypropyltriethoxysilane.

The silane coupling agent and the surfactant are contained in an amount of preferably 0.1 to 25.0 parts by mass, more preferably 0.1 to 10 parts by mass, and further preferably 0.1 to 2.0 parts by mass, based on 100 parts by mass of the inorganic filler (D).

By adjusting the content of the silane coupling agent or the surfactant to the preferable range, it is possible to suppress peeling at the adhesion interface due to volatilization of an excessive silane coupling agent and surfactant in a heating process in semiconductor assembling (for example, a reflow process), while suppressing aggregation of the inorganic filler (D). As a result, generation of voids can be suppressed.

Examples of the shape of the inorganic filler (D) include a flake shape, a needle shape, a filament shape, a spherical shape, and a scale shape. In terms of high filling and flowability, spherical particles are preferred.

In the adhesive composition of the present invention, the proportion of the inorganic filler (D) based on the total content of the components constituting the film adhesive (specifically, components other than the solvent, that is, the solid content) in the adhesive composition of the present invention is preferably from 5 to 70 vol %.

When the content is the above upper limit or less, generation of voids can be suppressed. Further, such a content proportion can decrease the curing shrinkage and lower the linear expansion coefficient as well as allows relaxing of internal stress generated in the semiconductor package during thermal change, and also allows improvement of an adhesive strength.

The proportion of the inorganic filler (D) is preferably from 20 to 70 vol %, more preferably from 20 to 60 vol %, still more preferably from 20 to 50% by volume, and still more preferably from 25 to 50 vol %. The proportion of the inorganic filler (D) may be from 30 to 70 vol %.

The content (vol %) of the inorganic filler (D) can be calculated from the contained mass and specific gravity of each component such as the epoxy resin (A), the epoxy resin curing agent (B), the polyurethane resin (C), and the inorganic filler (D).

### (Other Components)

The adhesive composition of the present invention may contain a polymer compound in addition to the epoxy resin (A), the epoxy resin curing agent (B), the polyurethane resin (C), and the inorganic filler (D) as long as the effects of the present invention are not impaired.

Examples of the polymer compound include natural rubber, butyl rubber, isoprene rubber, chloroprene rubber, silicone rubber, ethylene-vinyl acetate copolymer, ethylene-(meth)acrylic acid copolymer, ethylene-(meth)acrylic acid ester copolymer, polybutadiene resin, polycarbonate resin, thermoplastic polyimide resin, polyamide resin such as 6-nylon and 6,6-nylon, (meth)acrylic resin, polyester resin such as polyethylene terephthalate and polybutylene terephthalate, polyamideimide resin, fluororesin, or phenoxy resin. These polymer compounds may be used singly, or in combination of two or more kinds thereof.

The adhesive composition of the present invention may further contain, for example, an organic solvent (e.g., methyl ethyl ketone), an ion trapping agent (ion capturing agent), a curing catalyst, a viscosity adjusting agent, an antioxidant, a flame retardant, and/or a coloring agent. The adhesive layer can contain, for example, other additives described in WO 2017/158994 A.

The proportion of the total content of the epoxy resin (A), the epoxy resin curing agent (B), the polyurethane resin (C), and the inorganic filler (D) in the adhesive composition of the present invention can be, for example, 60 mass % or more, preferably 70 mass % or more, further preferably 80 mass % or more, and may also be 90 mass % or more. Also, the proportion may be 100 mass %, and can be 95 mass % or less.

The adhesive composition of the present invention can be suitably used for obtaining the film adhesive of the present invention. However, the adhesive composition of the present invention is not limited to for the film adhesive, and it can also be suitably used for obtaining a liquid adhesive.

The adhesive composition of the present invention can be obtained by mixing the above components at a temperature at which the epoxy resin (A) is practically not cured. The order of mixing is not particularly limited. Resin components such as the epoxy resin (A) and the polyurethane resin (C) may be mixed together with a solvent, if necessary, and then the inorganic filler (D) and the epoxy resin curing agent (B) may be mixed. In this case, the mixing in the presence of the epoxy resin curing agent (B) may be performed at a temperature at which the epoxy resin (A) is practically not cured, and the mixing of the resin components in the absence of the epoxy resin curing agent (B) may be performed at a higher temperature.

From the viewpoint of suppressing thermal curing of the epoxy resin (A), the adhesive composition of the present invention is preferably stored under a temperature condition at 10° C. or lower before use (before being formed into a film adhesive),

### [Film Adhesive]

The film adhesive of the present invention is a film adhesive obtained from the adhesive composition of the present invention. Thus, the above-described epoxy resin (A), epoxy resin curing agent (B), polyurethane resin (C), and inorganic filler (D) are included. Meanwhile, the polyurethane resin (C) has a storage elastic modulus at 25° C., in a dynamic viscoelastic analysis, of 8.0 MPa or higher. The proportion of the polyurethane resin (C) based on the total content of the epoxy resin (A) and the polyurethane resin (C) is from 2 to 50 mass %.

When the film adhesive of the present invention is formed using the adhesive composition containing an organic solvent, the solvent is usually removed from the adhesive composition by drying. Thus, the content of the solvent in the film adhesive of the present invention is 1000 ppm (ppm is on a mass basis) or less, and is usually 0.1 to 1000 ppm.

Here, the “film” in the present invention means a thin film having a thickness of 200 μm or less. The shape, size, and the like of the film are not particularly limited, and can be appropriately adjusted according to a use form.

The film adhesive of the present invention is in a state before curing, that is, in a state of B-stage.

The film adhesive of the present invention has a maximum tensile stress of 7.0 MPa or higher in the stress-strain curve when a tensile strength is applied to. The maximum tensile stress is preferably 8.0 MPa or larger, more preferably 9.0 MPa or larger, and still more preferably 10.0 MPa or larger from the viewpoint of enhancing the pre-cut processability. The upper limit of the maximum tensile stress is not particularly limited, but is preferably 30.0 MPa or less, more preferably 25.0 MPa or less, and also preferably 20.0 MPa or less. Thus, the maximum tensile stress is preferably from 7.0 to 30.0 MPa, more preferably from 8.0 to 25.0 MPa, still more preferably from 9.0 to 25 MPa, still more preferably from 10.0 to 25 MPa, and still more preferably from 10.0 to 20 MPa.

The maximum tensile stress can be controlled by, for example, the type, particle diameter, and content of the inorganic filler (D), the type and content of the epoxy resin (A) and the epoxy resin curing agent (B), in addition to the storage elastic modulus, Tg, and content of the polyurethane resin (C).

The maximum tensile stress can be determined by the method described in Examples described later.

In the present invention, the film adhesive before curing refers to one in which the epoxy resin (A) is in a state before thermal curing. The film adhesive before thermal curing specifically means a film adhesive which is not exposed to a temperature condition at 25° C. or higher after preparation of the film adhesive. On the other hand, the film adhesive after curing refers to one in which the epoxy resin (A) is thermally cured. The above description is intended to clarify the characteristics of the adhesive composition of the present invention, and the film adhesive of the present invention is not limited to one that is not exposed to a temperature condition at 25° C. or higher.

The film adhesive of the present invention can be suitably used as a die attach film in a semiconductor production process. In this case, the film adhesive of the present invention is excellent in pre-cut processability, lamination performance, and cutting performance during the dicing step.

The film adhesive of the present invention has a melt viscosity at 70° C. of preferably 50000 Pa-s or less and more preferably 40000 Pa-s or less when the film adhesive is heated at a temperature elevation rate of 5° C./min from 25° C., from the viewpoint of further enhancing the lamination performance. The lower limit of the melt viscosity at 70° C. is not particularly limited, but is preferably 100 Pa-s or higher and more preferably 10000 Pa-s or higher. Thus, the melt viscosity at 70° C. is preferably in the range of 100 to 50000 Pa-s and more preferably in the range of 10000 to 40000 Pa-s.

The melt viscosity can be determined by the method described in Examples described later.

The melt viscosity can be appropriately controlled by the content of the inorganic filler (D) and the kind of the inorganic filler (D) as well as the kinds and contents of coexisting compounds or resins such as the epoxy resin (A), epoxy resin curing agent (B), and the polyurethane resin (C).

The film adhesive of the present invention has a tensile elastic modulus, as obtained from a stress-strain curve when a tensile strength is applied, of preferably from 400 to 3000 MPa, more preferably from 500 to 2600 MPa, and still more preferably from 500 to 2000 MPa. When the tensile elastic modulus is within the above range, excellent pre-cut property, lamination performance, and cutting performance during the dicing step can be implemented at a higher level. The tensile elastic modulus is preferably low from the viewpoint of pre-cut processability, and is preferably high from the viewpoint of cutting performance during the dicing step.

The tensile elastic modulus can be determined by the method described in Examples described later.

The film adhesive of the present invention has a thickness of preferably 1 to 60 μm and more preferably 1 to 20 μm. The thickness can be from 3 to 30 μm or from 5 to 20 μm. Even when the film adhesive is made as a thin film, the effects of the present invention, including excellent pre-cut processability, lamination performance, and cutting performance during the dicing step, can be further exerted. From this viewpoint, the film adhesive preferably has a thickness of from 5 to 15 μm.

The thickness of the film adhesive can be measured by a contact type linear gauge method (desk-top contact type thickness measurement apparatus).

The film adhesive of the present invention can be formed by preparing the adhesive composition (varnish) of the present invention, applying the composition onto a release-treated substrate film, and drying the composition as necessary. The adhesive composition usually contains an organic solvent.

As the release-treated substrate film, any release-treated substrate film that functions as a cover film of the obtained film adhesive can be used, and a publicly known film can be appropriately employed. Examples thereof include release-treated polypropylene (PP), release-treated polyethylene (PE), release-treated polyethylene terephthalate (PET).

A publicly known method can be appropriately employed as an application method, and examples thereof include methods using a roll knife coater, a gravure coater, a die coater, a reverse coater, and the like.

The drying may be performed by removing the organic solvent from the adhesive composition without curing the epoxy resin (A) to form a film adhesive, and can be performed, for example, by holding the composition at a temperature of 80 to 150° C. for 1 to 20 minutes.

The film adhesive of the present invention may be formed of the film adhesive of the present invention alone, or may have a form obtained by bonding a release-treated substrate film described above to at least one surface of the film adhesive. Further, the film adhesive may be integrated with the dicing film, to form a dicing die attach film. The film adhesive of the present invention may be a form obtained by cutting the film into an appropriate size, or a form obtained by winding the film into a roll form.

In the film adhesive of the present invention, it is preferable that the arithmetic average roughness Ra of at least one surface thereof (that is, at least one surface to be bonded to an adherend) is 3.0 μm or less, and it is more preferable that the arithmetic average roughness Ra of surfaces on both sides to be bonded to the adherend is 3.0 μm or less.

The arithmetic average roughness Ra is more preferably 2.0 μm or less, and further preferably 1.5 μm or less. The lower limit is not particularly limited, but is practically 0.1 μm or more.

From the viewpoint of suppressing curing of the epoxy resin (A), the film adhesive of the present invention is preferably stored under a temperature condition at 10° C. or lower before use (before curing).

### [Semiconductor Package and Producing Method Thereof]

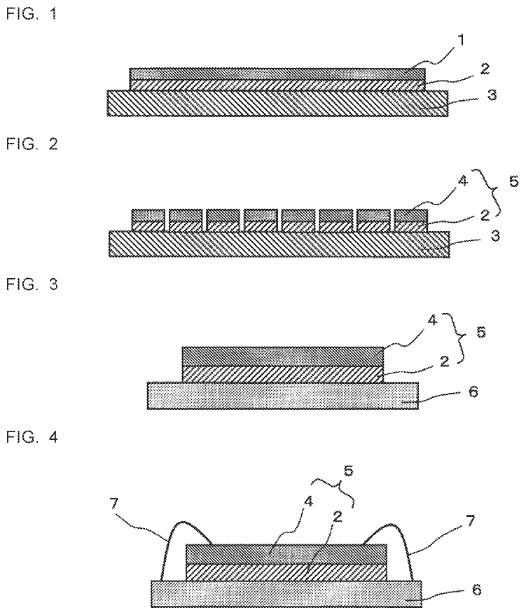

Then, preferred embodiments of a semiconductor package and a method of producing the same of the present invention will be explained in detail with reference to the drawings. Note that, in the explanations and drawings below, the same reference numerals are given to the same or corresponding components, and overlapping explanations will be omitted. FIGS. 1 to 7 are schematic longitudinal cross-sectional views each illustrating a preferred embodiment of each step of a method of producing a semiconductor package of the present invention.

In the method of producing a semiconductor package of the present invention, as a first step, as illustrated in FIG. 1, the film adhesive 2 (die attach film 2) of the present invention is thermocompression bonded to the back surface of a semiconductor wafer 1 in which at least one semiconductor circuit is formed on a surface (that is, the back surface is a surface of the semiconductor wafer 1 on which the semiconductor circuit is not formed) to provide an adhesive layer (film adhesive 2), and then a dicing film 3 (dicing tape 3) is provided with this adhesive layer (film adhesive 2) interposed therebetween. In FIG. 1, the film adhesive 2 is illustrated smaller than the dicing film 3, but the sizes (areas) of both films are appropriately set according to the purpose. For the condition of thermocompression bonding, thermocompression bonding is performed at a temperature at which the epoxy resin (A) is not thermally cured actually. Examples include the condition at a temperature of about 70° C. and a pressure of about 0.3 MPa.

As the semiconductor wafer 1, a semiconductor wafer where at least one semiconductor circuit is formed on the surface can be appropriately used. Examples thereof include a silicon wafer, a SiC wafer, a GaAs wafer, and a GaN wafer. In order to provide the film adhesive (die attach film) of the present invention on the back surface of the semiconductor wafer 1, for example, a publicly known apparatus such as a roll laminator or a manual laminator can be appropriately used.

In the above, the die attach film and the dicing film are separately attached. However, when the film adhesive of the present invention is in the form of a dicing die attach film, the film adhesive and the dicing film can be integrally bonded.

Next, as a second step, as illustrated in FIG. 2, the semiconductor wafer 1 and the adhesive layer (the die attach film 2) are integrally diced to give a semiconductor chip with an adhesive layer 5 on the dicing film 3, the semiconductor chip with an adhesive layer 5 including a semiconductor chip 4 obtained by dicing the semiconductor wafer and a piece of film adhesive 2 obtained by dicing the film adhesive 2. Further, an apparatus used for dicing is not particularly limited, and a common dicing apparatus can be appropriately used.

Next, as a third step, the dicing film is cured with energy rays as necessary to reduce the adhesive strength, and the semiconductor chip with an adhesive layer 5 is peeled off from the dicing film 3 by pickup. Then, as illustrated in FIG. 3, the semiconductor chip with an adhesive layer 5 and the circuit board 6 are thermocompression bonded via a piece of film adhesive 2 to mount the semiconductor chip with an adhesive layer 5 on the circuit board 6. As the circuit board 6, a substrate where a semiconductor circuit is formed on the surface can be appropriately used. Examples of such a substrate include a print circuit board (PCB), any of various lead frames, and a substrate where electronic components such as a resistive element and a capacitor are mounted on a surface of the substrate.

A method of mounting the semiconductor chip with an adhesive layer 5 on such a circuit board 6 is not particularly limited, and a conventional thermocompression bonding mounting method can be appropriately adopted.

Then, as a fourth step, the piece of film adhesive 2 is thermally cured. The temperature of the thermal curing is not particularly limited as long as the temperature is equal to or higher than a temperature at which thermal curing starts in the piece of film adhesive 2, and may be appropriately adjusted depending on the types of the epoxy resin (A), the polyurethane resin (C), and the epoxy curing agent (B) used. For example, the temperature is preferably from 100 to 1860° C. and more preferably from 140 to 180° C. from the viewpoint of curing in a shorter time. If the temperature is too high, the components in the piece of film adhesive 2 tend to volatilize and foam during the curing process. The duration of this thermal curing treatment may be appropriately set according to the heating temperature, and can be, for example, from 10 to 120 minutes.

In the method of producing a semiconductor package of the present invention, it is preferable that the circuit board 6 and the semiconductor chip with an adhesive layer 5 are connected via a bonding wire 7 as illustrated in FIG. 4. Such a connection method is not particularly limited, and a publicly known method, for example, a wire bonding method or a TAB (Tape Automated Bonding) method can be appropriately employed.

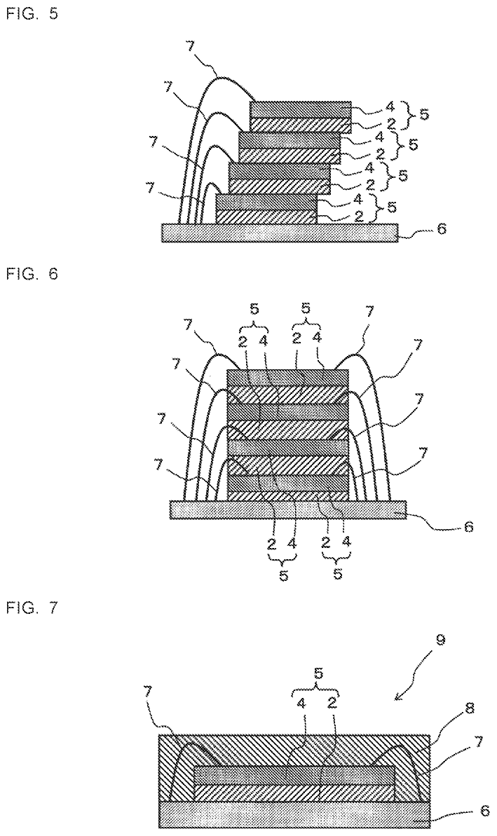

Further, a plurality of semiconductor chips 4 can be stacked by thermocompression bonding another semiconductor chip 4 to a surface of the mounted semiconductor chip 4, performing thermal curing, and then connecting the semiconductor chips 4 again to the circuit board 6 by wire bonding. Examples of the stacking method include a method of stacking the semiconductor chips in slightly different positions as illustrated in FIG. 5, and a method of stacking the semiconductor chips by increasing the thicknesses of the piece of film adhesive 2 of the second layer or later and thereby embedding the bonding wire 7 in each piece of film adhesive 2 as illustrated in FIG. 6.

In the method of producing a semiconductor package of the present invention, it is preferable to seal the circuit board 6 and the semiconductor chip with an adhesive layer 5 by using a sealing resin 8 as illustrated in FIG. 7. In this way, the semiconductor package 9 can be obtained. The sealing resin 8 is not particularly limited, and a publicly known sealing resin that can be used for the production of the semiconductor package can be appropriately used. In addition, a sealing method using the sealing resin 8 is not particularly limited, and a generally conducted method can be employed.

The semiconductor package of the present invention is produced by the above-described method of producing a semiconductor package. At least one site disposed between a semiconductor chip and a circuit board or between semiconductor chips is bonded with a thermally cured body of the film adhesive of the present invention.

### EXAMPLES

Hereinafter, the present invention will be described in more detail based on Examples and Comparative Examples. However, the present invention is not limited to the following Examples. Also, the room temperature means 250C, MEK is methyl ethyl ketone, IPA is isopropyl alcohol, and PET is polyethylene terephthalate. “%” and “part” are on a mass basis unless otherwise specified.

### Example 1

In a 1000-ml separable flask, 56 parts by mass of cresol novolac type epoxy resin (trade name: E0CN-104S; weight average molecular weight: 5000; softening point: 92° C.; solid; epoxy equivalent amount: 218 g/eq; manufactured by Nippon Kayaku Co., Ltd.), 49 parts by mass of bisphenol A type epoxy resin (trade name: YD-128; weight average molecular weight: 400; softening point: 25° C. or less; liquid; epoxy equivalent amount: 190 g/eq; manufactured by NSCC Epoxy Manufacturing Co., Ltd.), and 120 parts by mass of polyurethane resin solution (trade name: Dynaleo VA-9320M; weight average molecular weight of polyurethane resin: 120000; Tg: 39° C.; storage elastic modulus at 25° C.: 594 MPa; solvent: MEK/IPA mixed solvent; manufactured by TOYOCHEM CO., LTD.) (30 parts by mass as polyurethane resin) were heated with stirring at 110° C. for 2 hours, to prepare a resin varnish.

Subsequently, all of the resin varnish (225 parts by mass) was transferred to an 800-ml planetary mixer, and 196 parts by mass of alumina filler (trade name: AO-502; average particle diameter (d50): 0.6 μm; manufactured by Admatechs Co. Ltd.) was introduced to the mixer. Further, 2.0 parts by mass of imidazole type curing agent (trade name: 2PHZ-PW; manufactured by Shikoku Chemicals Corporation) and 3.0 parts by mass of silane coupling agent (trade name: S-510; manufactured by JNC Corporation) were introduced to the mixer. The contents were then mixed with stirring for 1 hour at room temperature. Then, defoaming under vacuum was conducted, thus obtaining a mixed varnish (adhesive composition).

Then, the obtained mixed varnish was applied and dried on a release-treated PET film (release film) having a thickness of 38 μm by using a multi coater (head part: a knife coater; model: MPC-400 L; manufactured by Matsuoka Machinery Co., Ltd.) under the conditions below, to produce a two-layer laminated film (film adhesive with a release film) in which a film adhesive layer having a width of 300 mm, a length of 10 m, and a thickness of 5 μm was formed on the release film.

Application and drying conditions:
Drying treatment temperature: 130° C. (drying furnace: 1.5 m); and
Linear velocity: 1.0 m/min (drying furnace residence time: 1.5 minutes).

The epoxy resin did not cure after the drying, and the same applies to the following Examples and Comparative Examples.

### Example 2

An adhesive composition and a two-layer laminated film were obtained in the same manner as in Example 1, except that 120 parts by mass of polyurethane resin solution (trade name: Dynaleo VA-9310MF; weight average molecular weight: 110000; Tg: 27° C.; storage elastic modulus at 25° C.: 289 MPa; solvent: MEK/IPA mixed solvent; manufactured by TOYOCHEM CO., LTD.) (30 parts by mass as polyurethane resin) was used as the polyurethane resin.

### Example 3

An adhesive composition and a two-layer laminated film were obtained in the same manner as in Example 1, except that 120 parts by mass of polyurethane resin solution (trade name: Dynaleo VA-9303MF; weight average molecular weight: 105000; Tg: 4° C.; storage elastic modulus at 25° C.: 100 MPa; solvent: MEK/IPA mixed solvent; manufactured by TOYOCHEM CO., LTD.) (30 parts by mass as polyurethane resin) was used as the polyurethane resin.

### Example 4

An adhesive composition and a two-layer laminated film were obtained in the same manner as in Example 1, except that 120 parts by mass of polyurethane resin solution (trade name: Dynaleo VA-9302MF; weight average molecular weight: 95000; Tg: −5° C.; storage elastic modulus at 25° C.: 8.7 MPa; solvent: MEK/IPA mixed solvent; manufactured by TOYOCHEM CO., LTD.) (30 parts by mass as polyurethane resin) was used as the polyurethane resin.

### Example 5

An adhesive composition and a two-layer laminated film were obtained in the same manner as in Example 2, except that the amount of the polyurethane resin solution blended was 240 parts by mass (60 parts by mass as polyurethane resin) and the amount of the alumina filler blended was 238 parts by mass.

### Example 6

An adhesive composition and a two-layer laminated film were obtained in the same manner as in Example 2, except that the amount of the polyurethane resin solution blended was 360 parts by mass (90 parts by mass as polyurethane resin) and the amount of the alumina filler blended was 281 parts by mass.

### Example 7

An adhesive composition and a two-layer laminated film were obtained in the same manner as in Example 2, except that the amount of the polyurethane resin solution blended was 40 parts by mass (10 parts by mass as polyurethane resin) and the amount of the alumina filler blended was 168 parts by mass.

### Example 8

An adhesive composition and a two-layer laminated film were obtained in the same manner as in Example 2, except that the amount of the alumina filler blended was 305 parts by mass.

### Example 9

An adhesive composition and a two-layer laminated film were obtained in the same manner as in Example 2, except that the amount of the alumina filler blended was 375 parts by mass.

### Example 10

An adhesive composition and a two-layer laminated film were obtained in the same manner as in Example 2, except that instead of the alumina filler, 522 parts by mass of silver filler (trade name: AG-4-8F; average particle diameter (d50): 2.0 μm; manufactured by DOWA ELECTRONICS MATERIALS CO., LTD.) was used.

### Example 11

An adhesive composition and a two-layer laminated film were obtained in the same manner as in Example 2, except that instead of the alumina filler, 209 parts by mass of silica filler (trade name: SO-25R; average particle diameter (d50): 0.5 μm; manufactured by Admatechs Co. Ltd.) was used.

### Comparative Example 1

An adhesive composition and a two-layer laminated film were obtained in the same manner as in Example 1, except that 30 parts by mass of polyurethane resin (trade name: T-8175N: weight average molecular weight: 80000; Tg: −23° C.; storage elastic modulus at 25° C.: 3.4 MPa; manufactured by DIC Covestro Polymer Ltd.) was used as the polyurethane resin, and 90 parts by mass of cyclohexanone was further blended.

### Comparative Example 2

An adhesive composition and a two-layer laminated film were obtained in the same manner as in Example 1, except that instead of the polyurethane resin, 30 parts by mass of acrylic resin (trade name: SG-280EK23; weight average molecular weight: 800000; Tg: −29° C.; storage elastic modulus at 25° C.: 6.5 MPa; manufactured by Nagase ChemteX Corporation) was used, and 90 parts by mass of cyclohexanone was further blended.

### Comparative Example 3

An adhesive composition and a two-layer laminated film were obtained in the same manner as in Example 1, except that instead of the polyurethane resin, 30 parts by mass of bisphenol A type phenoxy resin (trade name: YP-50; weight average molecular weight: 70000; Tg: 85° C.; storage elastic modulus at 25° C.: 1700 MPa; manufactured by NSCC Epoxy Manufacturing Co., Ltd.) was used, and 90 parts by mass of MEK was further blended.

### Comparative Example 4

An adhesive composition and a two-layer laminated film were obtained in the same manner as in Example 2, except that the amount of the polyurethane resin solution blended was 520 parts by mass (130 parts by mass as polyurethane resin) and the amount of the alumina filler blended was 337 parts by mass.

### Comparative Example 5

An adhesive composition and a two-layer laminated film were obtained in the same manner as in Example 2, except that the amount of the polyurethane resin solution blended was 8 parts by mass (2 parts by mass as polyurethane resin) and the amount of the alumina filler blended was 157 parts by mass.

Tables 1 and 2 show the compositions of the film adhesives prepared in the respective Examples or Comparative Examples. An empty cell means that a corresponding component is not contained.

The “Inorganic filler content” shown in Tables 1 and 2 indicates the proportion (vol %) of the inorganic filler based on the total content of the epoxy resin, the epoxy resin curing agent, the polymer, the silane coupling agent, and the inorganic filler.

### Test Examples

### <Measurement of Storage Elastic Modulus and Glass Transition Temperature>

Solutions of each of the polyurethane resin, the acrylic resin, and the phenoxy resin used in Examples or Comparative Examples were prepared. The resins obtained in the solution state were used as they were. The resins obtained in the solid state were made into a solution by using the solvent described in the corresponding Example or Comparative Example. Thereafter, each solution was applied onto a release-treated PET film (release film) having a thickness of 38 μm and dried by heating at 130° C. for 10 minutes, thereby producing a two-layer laminated film in which a resin film having a length of 300 mm, a width of 200 mm, and a thickness of 30 μm is formed on the release film. Each of the resulting resin films was cut into a size of 5 mm×17 mm and the release film was then removed. Each of the cut films was measured by using a dynamic viscoelastic analyzer (trade name: Rheogel-E4000F, manufactured by UBM) under the condition at a measurement temperature range of 20 to 300° C., a temperature elevation rate of 5° C./min, and a frequency of 1 Hz. The storage elastic modulus and tan δ at each temperature were thus measured. The storage elastic modulus at 25° C. was read from the measured value, and the tan δ peak top temperature (temperature at which tan δ exhibits the maximum) was taken as the glass transition temperature (Tg). Each measured value was indicated with the polymer name in the Tables.

### <Measurement of Maximum Tensile Stress and Tensile Elastic Modulus>

A rectangle having a size of 20 mm×50 mm was cut out from the film adhesive with a release film as obtained in each Example or Comparative Example, and the cut film adhesives were laminated with the release film peeled off. This laminate was bonded using a hand roller on a stage of a hot plate at 70° C., to give a test piece with a thickness of 40 μm. This test piece was pulled at an inter-grip distance of 14 mm and a tension rate of 500 mm/min under an environment in a temperature range of 25° C. and at a humidity of 60% while using a tensile tester (RTF 2430, manufactured by A&D Company, Limited), and the change in strain (displacement) against the test strength was measured. The tensile stress was calculated by dividing the test strength by the cross-sectional area of the test piece. From the obtained stress-strain curve, the maximum tensile stress and the tensile elastic modulus were calculated under the following analysis conditions.

Maximum tensile stress (MPa): maximum tensile stress in the obtained stress-strain curve.

Tensile elastic modulus (MPa): elastic modulus calculated as an inclination between a point corresponding to the test strength (stress) 3 N and a point corresponding to the test strength 7 N on the obtained stress-strain curve.

### <Measurement of Melt Viscosity Before Curing>

A square having a size of 5.0 cm (length)×5.0 cm (width) was cut out from the film adhesive with a release film as obtained in each Example or Comparative Example, and the cut film adhesives were laminated with the release film peeled off. This laminate was bonded using a hand roller on a stage at 70° C., to give a test piece with a thickness of about 1.0 mm. A change in viscosity resistance in a temperature range of 20 to 25° C. at a temperature elevation rate of 5° C./min was measured for this test piece by using a rheometer (RS6000, manufactured by Haake). The melt viscosities at 70° C. (Pas) of the film adhesive before curing were each calculated from the obtained temperature-viscosity resistance curve.

### <Pre-Cut Processability>

The film adhesive (die attach film) of the film adhesive with a release film as obtained in each Example or Comparative Example was cut so that a circle (diameter: 220 mm) capable of covering the back surface of the semiconductor wafer was repeatedly formed over the entire length (10 m) at intervals (58.6 mm) in the length direction. While the circular portions were left on the release film, an unnecessary portion of the film adhesive on the outer side of the circular portions was wound up by using a film winding machine (MS3-600 A-T, manufactured by Yutaka Seisakusho, Limited) at a tension of 16 N while changing the winding speed. According to the winding length at which breakage occurred at each winding speed, the pre-cut processability was evaluated under the following criteria. The winding length was determined from the rotation length of the winding roller while the time point at which winding was started was set to 0 m. The higher the winding speed, the more likely a break will occur under the condition.

—Evaluation Criteria—

AA: The film adhesive is not broken when wound at a winding speed of 5 m/min.

A: The film adhesive is broken when wound at a winding speed of 5 m/min, but the film adhesive is not broken when wound at a winding speed of 2 m/min.

B: At the time of winding at a winding speed of 2 m/min, no breakage occurs at the time of a winding length of 1 m, and breakage occurs during the subsequent winding.

C: At the time of winding at a winding speed of 2 m/min, breakage occurs at a winding length of less than 1 m.

### <Evaluation of Wafer Lamination Performance>

The film adhesive with a release film as obtained in each Example or Comparative Example was bonded to one surface of a dummy silicon wafer (size: 8 inch, thickness: 50 μm) by using a manual laminator (trade name: FM-114, manufactured by Technovision, Inc.) at a temperature of 70° C. and a pressure of 0.1 MPa or 0.3 MPa. The bonding surface was visually observed, and the wafer lamination performance was evaluated according to the following criteria. The lower the lamination pressure, the more easily voids are formed under the lamination condition.

—Evaluation criteria—

AA: No void is observed in a semiconductor wafer laminated under the condition of a lamination pressure of 0.1 MPa.

A: In a semiconductor wafer laminated under the condition of a lamination pressure of 0.1 MPa, one or more voids are observed, but no voids are observed under the condition of a lamination pressure of 0.3 MPa.

B: 1 or more and 4 or less voids are observed in a semiconductor wafer laminated under the condition of a lamination pressure of 0.3 MPa.

C: 5 or more voids are observed in a semiconductor wafer laminated under the condition of a lamination pressure of 0.3 MPa.

### <Evaluation of Cutting Performance During Dicing>

The film adhesive with a release film as obtained in each Example or Comparative Example was first bonded to one surface of a dummy silicon wafer (size: 8 inch, thickness: 50 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing film (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator at room temperature and a pressure of 0.3 MPa. Then, dicing was performed from the dummy silicon wafer side to form squares each having a size of 5 mm×5 mm by using a dicing apparatus (trade name: DFD-6340, manufactured by DISCO Corporation) equipped with two axes of dicing blades (Z1: NBC-ZH2050 (27HEDD), manufactured by DISCO Corporation, Z2: NBC-ZH127F-SE(BC), manufactured by DISCO Corporation) under conditions at a rotation speed of 40000 rpm (for both Z1 and Z2) and a height (the shortest distance from the stage surface to the dicing blade tip during dicing) of 125 μm (Z1) or 70 μm (Z2) while changing the cutting speed, to prepare each dummy chip with a film adhesive. Each obtained dummy chip with a film adhesive was observed from the side surface with a stereoscopic microscope, and cutting performance during dicing was evaluated under the following criteria. Five random dummy chips with a film adhesive were observed, at each cutting speed. As the cutting speed becomes faster, more heat is generated during dicing, and cutting debris are more likely to occur.

—Evaluation Criteria—

AA: No cutting debris are observed in all the dummy chips with a film adhesive among the 5 dummy chips with a film adhesive as obtained by dicing under the condition at a cut speed of 50 mm/sec.

A: Cutting debris are observed in one or more dummy chips with a film adhesive among the 5 dummy chips with a film adhesive as obtained by dicing under the condition at a cut speed of 50 mm/sec, but no cutting debris are observed in all the dummy chips with a film adhesive among the 5 dummy chips with a film adhesive as obtained by dicing under the condition at a cut speed of 20 mm/sec.

B: Cutting debris are observed in 1 or more and 3 or less dummy chips with a film adhesive among the 5 dummy chips with a film adhesive as obtained by dicing under the condition at a cut speed of 20 mm/sec.

C: Cutting debris are observed in 4 or more dummy chips with a film adhesive among the 5 dummy chips with a film adhesive as obtained by dicing under the condition at a cut speed of 20 mm/sec.

The above respective test results are shown in the following Tables.

TABLE 1

| | | | Ex. | | | | | |
|---|---|---|---|---|---|---|---|---|
| Standard | | | 1 | 2 | 3 | 4 | 5 | 6 |
| Film adhesive | Epoxy resin | EOCN-104S (cresol novolac type | 56 | 56 | 56 | 56 | 56 | 56 |
| Composition | | epoxy resin) | | | | | | |
| (parts by mass) | | YD-128 (liquid Bis A-type epoxy | 49 | 49 | 49 | 49 | 49 | 49 |
| | | resin) | | | | | | |
| | Polymer | VA-9320M (polyurethane | 30 | | | | | |
| | | resin)/Tg 39° C., 594 MPa | | | | | | |
| | | VA-9310MF (polyurethane | | 30 | | | 60 | 90 |
| | | resin)/Tg 27° C., 289 MPa | | | | | | |
| | | VA-9303MF (polyurethane | | | 30 | | | |
| | | resin)/Tg 4° C., 100 MPa | | | | | | |
| | | VA-9302MF (polyurethane | | | | 30 | | |
| | | resin)/Tg −5° C., 8.7 MPa | | | | | | |
| | Inorganic | AO502 (average particle diameter: | 196 | 196 | 196 | 196 | 238 | 281 |
| | filler | 0.6 μm; alumina filler) | | | | | | |
| | | AG-4-8F (average particle | | | | | | |
| | | diameter: 2.0 μm; silver filler) | | | | | | |
| | | SO-25R (average particle diameter: | | | | | | |
| | | 0.5 μm; silica filler) | | | | | | |

| | | | | | | |
|---|---|---|---|---|---|---|
| S-510 (Epoxysilane-type silane coupling agent) | 3 | 3 | 3 | 3 | 3 | 3 |
| 2PHZ-PW (Imidazole-type curing agent) | 2 | 2 | 2 | 2 | 2 | 2 |
| Total solid content | 335 | 335 | 335 | 335 | 407 | 480 |
| Inorganic filler content (vol %) | 30.0% | 30.0% | 30.0% | 30.0% | 30.0% | 30.0% |
| Proportion of polymer resin based on total of | 22.4% | 22.4% | 22.4% | 22.4% | 36.6% | 46.4% |
| epoxy resin and polymer resin | | | | | | |

| | | | | | | |
|---|---|---|---|---|---|---|
| Maximum tensile stress (MPa) | 13 | 12 | 10 | 9.5 | 18 | 20 |
| Tensile elastic modulus (MPa) | 1000 | 930 | 500 | 400 | 600 | 520 |
| Melt viscosity at 70° C. before curing | 33000 | 29400 | 28300 | 28300 | 32300 | 49500 |
| Evaluation of pre-cut processability | AA | AA | AA | A | AA | AA |
| Evaluation of wafer lamination performance | AA | AA | AA | AA | AA | A |
| Evaluation of cutting performance during dicing | AA | AA | AA | A | AA | AA |

| | | | Ex. | | | | |
|---|---|---|---|---|---|---|---|
| Standard | | | 7 | 8 | 9 | 10 | 11 |
| Film adhesive | Epoxy resin | EOCN-104S (cresol novolac type | 56 | 56 | 56 | 56 | 56 |
| Composition | | epoxy resin) | | | | | |
| (parts by mass) | | YD-128 (liquid Bis A-type epoxy | 49 | 49 | 49 | 49 | 49 |
| | | resin) | | | | | |
| | Polymer | VA-9320M (polyurethane | | | | | |
| | | resin)/Tg 39° C., 594 MPa | | | | | |
| | | VA-9310MF (polyurethane | 10 | 30 | 30 | 30 | 30 |
| | | resin)/Tg 27° C., 289 MPa | | | | | |
| | | VA-9303MF (polyurethane | | | | | |
| | | resin)/Tg 4° C., 100 MPa | | | | | |
| | | VA-9302MF (polyurethane | | | | | |
| | | resin)/Tg −5° C., 8.7 MPa | | | | | |
| | Inorganic | AO502 (average particle diameter: | 168 | 305 | 375 | | |
| | filler | 0.6 μm; alumina filler) | | | | | |
| | | AG-4-8F (average particle | | | | 522 | |
| | | diameter: 2.0 μm; silver filler) | | | | | |
| | | SO-25R (average particle diameter: | | | | | 209 |
| | | 0.5 μm; silica filler) | | | | | |

| | | | | | |
|---|---|---|---|---|---|
| S-510 (Epoxysilane-type silane coupling agent) | 3 | 3 | 3 | 3 | 3 |
| 2PHZ-PW (Imidazole-type curing agent) | 2 | 2 | 2 | 2 | 2 |
| Total solid content | 287 | 444 | 514 | 661 | 348 |
| Inorganic filler content (vol %) | 30.0% | 40.0% | 45.0% | 30.0% | 45.0% |
| Proportion of polymer resin based on total of | 8.8% | 22.4% | 22.4% | 22.4% | 22.4% |
| epoxy resin and polymer resin | | | | | |

| | | | | | |
|---|---|---|---|---|---|
| Maximum tensile stress (MPa) | 10 | 10.3 | 9.8 | 16.5 | 14.9 |
| Tensile elastic modulus (MPa) | 1020 | 2350 | 2540 | 530 | 580 |
| Melt viscosity at 70° C. before curing | 18230 | 35840 | 38000 | 24530 | 39850 |
| Evaluation of pre-cut processability | AA | A | A | AA | AA |
| Evaluation of wafer lamination performance | AA | AA | AA | AA | AA |
| Evaluation of cutting performance during dicing | AA | AA | AA | AA | AA |

Remarks: ‘Ex.’ means Example according to this invention.

TABLE 2

| | | | CEx. | | | | |
|---|---|---|---|---|---|---|---|
| Standard | | | 1 | 2 | 3 | 4 | 5 |
| Film adhesive | Epoxy resin | EOCN-104S (cresol novolac type | 56 | 56 | 56 | 56 | 56 |
| Composition | | epoxy resin) | | | | | |
| (parts by mass) | | YD-128 (liquid bisA-type epoxy | 49 | 49 | 49 | 49 | 49 |
| | | resin) | | | | | |
| | Polymer | T-8175N (polyurethane resin)/ | 30 | | | | |
| | | Tg −23° C., 3.4 MPa | | | | | |
| | | SG-280EK23 (acrylic resin)/ | | 30 | | | |
| | | Tg −29° C., 6.5 MPa | | | | | |
| | | YP-50 (bisA-type phenoxy | | | 30 | | |
| | | resin)/Tg 85° C., 1700 MPa | | | | | |
| | | VA-9310MF (polyurethane | | | | 130 | 2 |
| | | resin)/Tg 27° C., 289 MPa | | | | | |
| | Inorganic | AO502 (average particle diameter: | 196 | 196 | 196 | 337 | 157 |
| | filler | 0.6 μm; alumina filler) | | | | | |

| | | | | | |
|---|---|---|---|---|---|
| S-510 (epoxysilane type silane coupling agent) | 3 | 3 | 3 | 3 | 3 |
| 2PHZ-PW (imidazole-type curing agent) | 2 | 2 | 2 | 2 | 2 |
| Total solid content | 335 | 335 | 335 | 576 | 268 |
| Inorganic filler content (vol %) | 30.0% | 30.0% | 30.0% | 30.0% | 30.0% |
| Proportion of polymer resin based on total of | 22.4% | 22.4% | 22.4% | 55.6% | 1.9% |
| epoxy resin and polymer resin | | | | | |

| | | | | | |
|---|---|---|---|---|---|
| Maximum tensile stress (MPa) | 9 | 6.8 | 4.5 | 22 | 6.9 |
| Tensile elastic modulus (MPa) | 370 | 390 | 3200 | 480 | 2400 |
| Melt viscosity at 70° C. before curing | 27000 | 52130 | 34650 | 88600 | 17430 |
| Evaluation of pre-cut processability | A | B | C | AA | B |
| Evaluation of wafer lamination performance | AA | B | AA | C | AA |
| Evaluation of cutting performance during dicing | C | B | AA | A | AA |

Remarks: ‘CEx.’ means Comparative Example.

Tables 1 and 2 above have revealed the results such that when the storage elastic modulus at 25° C. of the polyurethane resin used in the film adhesive was lower than the storage elastic modulus specified in the present invention, cutting debris were likely to occur during dicing (Comparative Example 1).

When the resins other than the polyurethane resins were applied as a resin to be combined with epoxy resin, the results were as follows. When the acrylic resin was used, the maximum tensile stress defined in the present invention was unable to be satisfied, and all of the pre-cut processability, the wafer lamination performance, and the cutting performance during dicing were poor in the results (Comparative Example 2). Meanwhile, even when the phenoxy resin was used instead of the polyurethane resin, the maximum tensile stress defined in the present invention was unable to be satisfied, and the pre-cut processability was also poor in the results

### Comparative Example 3

In addition, even in the case of using the polyurethane resin defined in the present invention, voids were generated at the time of bonding when the content was larger than the amount defined in the present invention (Comparative Example 4). On the other hand, when the content of the polyurethane resin was smaller than the amount specified in the present invention, the maximum tensile stress specified in the present invention was unable to be satisfied, and furthermore, the pre-cut processability was poor in the results (Comparative Example 5).

In contrast, in any of the film adhesives having the component composition specified in the present invention, unnecessary portions were reliably wound at the time of pre-cut processing, voids were hardly generated at the time of bonding, and cutting debris were unlikely to occur at the time of cutting processing (Examples 1 to 11).

Having described our invention as related to the present embodiments, it is our intention that the present invention not be limited by any of the details of the description, unless otherwise specified, but rather be construed broadly within its spirit and scope as set out in the accompanying claims.

The present application claims priority of Patent Application No. 2021-213386 filed in Japan on Dec. 27, 2021, which is herein incorporated by reference as part of the present specification.

### DESCRIPTION OF SYMBOLS

1 Semiconductor wafer
2 Adhesive layer (film adhesive)
3 Dicing film (dicing tape)
4 Semiconductor chip
Semiconductor chip with a film adhesive
6 Circuit board
7 Bonding wire
8 Sealing resin
9 Semiconductor package

1. An adhesive composition comprising:
an epoxy resin (A);
an epoxy resin curing agent (B);
a polyurethane resin (C); and
an inorganic filler (D),
wherein the polyurethane resin (C) has a storage elastic modulus at 25° C., in a dynamic viscoelastic analysis, of 8.0 MPa or higher,
wherein a proportion of the polyurethane resin (C) based on a total content of the epoxy resin (A) and the polyurethane resin (C) is from 2.0 to 50.0 mass %, and
wherein a maximum tensile stress in a stress-strain curve when a tensile strength is applied to a film adhesive formed using the adhesive composition is 7.0 MPa or higher.

2. The adhesive composition according to claim 1, wherein when the film adhesive formed using the adhesive composition is heated at a temperature elevation rate of 5° C./min from 25° C., a melt viscosity at 70° C. is 50000 Pa·s or less.

3. A film adhesive obtained from the adhesive composition according to claim 1.

4. The film adhesive according to claim 3, which has a thickness of 1 to 20 μm.

5. A method of producing a semiconductor package, comprising:
a first step of providing an adhesive layer by thermocompression bonding the film adhesive according to claim 3 to a back surface of a semiconductor wafer in which at least one semiconductor circuit is formed on a surface, and providing a dicing film via the adhesive layer;
a second step of dicing the semiconductor wafer and the adhesive layer simultaneously to obtain a semiconductor chip with an adhesive layer, which includes the semiconductor chip and a piece of the film adhesive; on the dicing film;
a third step of peeling the semiconductor chip with an adhesive layer off from the dicing film, and thermocompression bonding the semiconductor chip with an adhesive layer and a circuit board via the adhesive layer; and
a fourth step of thermally curing the adhesive layer.

6. A semiconductor package wherein a semiconductor chip and a circuit board, or semiconductor chips are bonded via a thermally cured body of the film adhesive according to claim 3.
